(19) United States
(12) Patent Application Publication
(10) Pub. No.: US 2024/0317904 A1
(43) Pub. Date: Sep. 26, 2024

(54) Fading

(71) Applicant: XETOS AG, Hohenbrunn (DE)

(72) Inventor: Frank Knocke, Ebersberg (DE)

(21) Appl. No.: 18/276,746

(22) PCT Filed: Feb. 11, 2022
(86) PCT No.: PCT/EP2022/053414

§ 371 Date: Aug. 10, 2023

(30) Foreign Application Priority Data
Feb. 11, 2021 (EP) 21156695.5

(51) Int. Cl. C08F 2/44; C08F 2/50; G02B 27/01; G03F 7/00; G03F 7/028

(52) U.S. Cl. CPC C08F 2/44; C08F 2/50; G02B 27/0103; G03F 7/001; G03F 7/028; G02B 2027/0109

(57) ABSTRACT

The present invention relates to UV/VIS photopolymerizable compositions and elements prepared therefrom and their use. In particular to recording materials for optical elements with refractive index modulation, especially holograms.

### CROSS-REFERENCE TO RELATED APPLICATIONS

This application is the United States national phase of International Application No. PCT/EP2022/053414 filed Feb. 11, 2022, and claims priority to European Patent Application No. 21156695.5 filed Feb. 11, 2021, the disclosures of which are hereby incorporated by reference in their entireties.

### BACKGROUND OF THE INVENTION

### Field of the Invention

The present invention relates to UV/VIS photopolymerisable compositions and elements made therefrom and their use. In particular, to recording materials for optical elements with refractive index modulation, especially holograms.

### Description of Related Art

In order for photopolymerisable compositions to be cured with visible light, they need an appropriate photoinitiator system which absorbs the energy of the light, forms free radicals and initiates the chain reaction of radical polymerisation.

Such systems are known and are described, for example, in application DE 69032682 T2 by DuPont, WO 2010091795 A1 by Bayer and in EP 1779196 B1 by Xetos.

They use a dye as a sensitizer and a borate salt as a co-initiator. The color is used to set the light to which the system is sensitive. Fluorescent dyes with the complementary color of the exposure wavelength are preferably used in order to effectively absorb the energy of the light. For example, a magenta dye is used for a green light, a blue dye for red and a yellow dye for blue. Combinations are also possible for exposure with different wavelengths.

To advantageously achieve high photosensitivity, sufficient and clear coloration of the photopolymerisable composition is necessary. However, for most applications of the exposed elements, a clear, transparent and colorless layer is desirable. Advantageously, these dyes are not lightfast and more or less fade under UV. But depending on the dye, this can take some time and high irradiances, and so a clearly perceptible residual coloration usually remains after the UV curing that takes place after laser exposure.

### SUMMARY OF THE INVENTION

The present invention is therefore based on the object of providing a system that fades faster and more effectively under UV light. And this without any loss of quality and additional work steps.

The object is solved according to the invention by a photopolymerisable composition which is curable by UV/VIS irradiation, comprising:
a) from 80 to 99.8 wt. % a radically curable monomer-containing mixture,
b) from 0.1 to 10% by weight of a photoinitiator system, and
(c) from 0.1 to 10% by weight of a bleaching agent,
wherein the total amount of a), b) and c) is 100% by weight and wherein the bleaching agent is effective under actinic irradiation. Particularly preferably, the bleaching substances are only formed by the actinic irradiation. Particularly preferably, bleaching substances are formed by the action of actinic radiation from component c).

### BRIEF DESCRIPTION OF THE DRAWINGS

FIG. 1 shows the schematic exposure setup;

FIG. 2 shows the beam path;

FIG. 3 shows the measurement curve with the corresponding measurement points of sample B; and

FIG. 4 shows the spectral absorption curves of the two photopolymerized compositions A and B before and after the 30 s bleaching under the UV bridge.

### DESCRIPTION OF THE INVENTION

Actinity (actinic radiation) can be understood as the photochemical activity of electromagnetic radiation of different wavelengths.

The term is used, for example, when evaluating the physiological consequences of laser light of different colors or the spectral sensitivity of photographic films and papers. In photochemistry, actinic chemicals are those that are sensitive to light or radiation.

In the context of the present invention, “effective under actinic irradiation” can mean that brightening occurs.

The photopolymerizable composition according to the invention is preferably used for the production of elements with a refractive index modulation, in particular holograms. The preparation of these elements is generally carried out by applying a spatially or interferometrically modulated radiation to a layer of the photopolymerisable composition deposited on a support substrate or a copy template. The carrier substrates used for the production of the elements according to the invention may be glass, plastic, in particular PET, PP, PMMA, polycarbonate or cellulose di- or triacetate, or paper. During exposure, the photopolymerisable composition may be located, for example, between two glass plates.

Preferred is an element comprising a component obtainable by the action of UV/VIS radiation, preferably actinic UV/VIS radiation, on the photopolymerisable composition according to the invention.

Particularly preferred is an element comprising a hologram obtainable by the action of spatially or interferometrically modulated radiation on the photopolymerisable composition according to the invention.

Particularly preferred is an element according to the invention comprising a hologram so obtainable and bleached by UV radiation.

Preferably, a manufacturing process is used that re-bleaches the element with UV light after UV/VIS exposure.

Preferably, the element is used as a film, lens, grating, prism, mirror, beam splitter, diffuser, surface relief, optical switch or sensor. And especially preferably used for a head-up display, laminated glass, data glasses, light guidance system, spectrometer, detection system, security element or label.

Another object of the invention is a method of forming a light stable hologram in a photopolymerisable layer on a substrate surface or a copy master, comprising exposing a layer of the photopolymerisable composition according to the invention to modulated radiation carrying holographic information.

### Bleaching Agent

Surprisingly, it was found that the decay products of certain photoinitiators produced during actinic irradiation contribute to better and faster fading of the dyes.

These are photoinitiators which are constructed as follows. An aryl ketone compound represented by the following general formula (1),

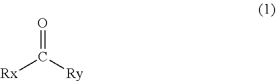

wherein Rx and Ry are the same or different and represent a straight or branched alkyl group having 1 to 8 carbon atoms and optionally substituted with a hydroxyl group, a cycloalkyl group having 1 to 8 carbon atoms and optionally substituted with a hydroxyl group, an alkoxy group having 1 to 8 carbon atoms and optionally substituted with a hydroxyl group, an alkoxycarbonyl group (the alkoxy group of which has 1 to 8 carbon atoms) and optionally substituted with a hydroxyl group, a carbamoyl group optionally substituted with a phosphate group, a phosphoryl group optionally substituted by an alkyl group having 1 to 8 carbon atoms or an aryl group having 6 to 8 carbon atoms, an acyl group or a condensed acyl group optionally substituted with a hydroxyl group, or a group represented by the formula (2);

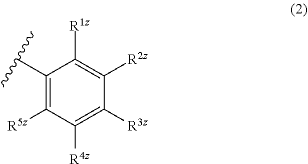

in the formula (2), R^{1z} to R^{5z} are the same or different and represent a hydrogen atom, an alkyl group having 1 to 8 carbon atoms, an alkenyl group having 2 to 8 carbon atoms, an alkoxy group having 1 to 8 carbon atoms, an alkyl group having 1 to 8 carbon atoms and substituted with halogen atoms, an alkoxy group having 1 to 8 carbon atoms and substituted with halogen atoms, a halogen atom, a hydroxyl group, a nitro group, a cyano group, an amino group, wherein in the formula (2), any two adjacent groups from R^{1z} to R^{5z} optionally bond together to form a condensed ring selected from naphthalene ring, quinoline ring, isoquinoline ring, tetrahydronaphthalene ring, indane ring, tetrahydroquinoline ring and tetrahydroisoquinoline ring together with the benzene ring to which they bond, and the carbon atoms to which two adjacent groups of R^{1z} to R^{5z} bond are optionally substituted with 1 to 4 of the same or different substituents selected from an alkyl group of 1 to 8 carbon atoms, a cycloalkyl group having 3 to 8 carbon atoms, an alkenyl group having 2 to 8 carbon atoms, an alkoxy group having 1 to 8 carbon atoms, and optionally substituted with halogen atoms, hydroxyl group, nitro group, cyano group, amino group, wherein at least one of Rx and Ry is represented by the formula (2).

The following photoinitiators and reactions are preferred.

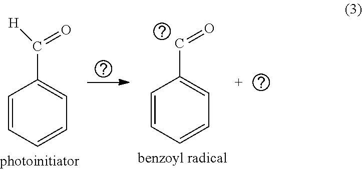 [SMILES: O=Cc1ccccc1 ; O=Cc1ccccc1]

And particularly preferably 2-hydroxy-2-methyl-1-phenylpropanones.

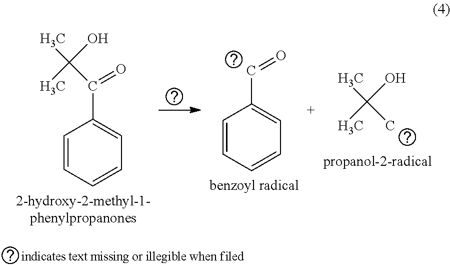

The bleaching agent c) in the photopolymerisable composition comprises one or more of these photoinitiators or their decomposition products or a mixture of these components.

The proportion of suitable photoinitiators in the bleaching agent may be more than 50% by weight, preferably more than 90% by weight. Particularly preferably, the bleaching agent consists exclusively of one or more suitable photoinitiators.

The preferred decomposition products are benzoyl derivatives and alcohols, particularly preferred decomposition products are benzaldehyde and 2-propanol.

Preferably, component c) of the photopolymerisable composition according to the invention contains photoinitiators, wherein the photoinitiators used in component c) particularly preferably generate benzoyl and alcohol radicals under the action of actinic radiation.

To obtain the desired decomposition products, a mixture of two photoinitiators can also be used, whereby under irradiation the first photoinitiator forms the benzoyl radical and the second photoinitiator forms the alcohol radical.

It is particularly preferred that the bleaching substances and the bleaching effect are only produced by actinic irradiation. In order for these substances to act effectively, an appropriate dosage is necessary, which may be higher than the otherwise usual recommended amount for photoinitiators. Preferred is a proportion of at least 1 wt. %, particularly preferred at least 3 wt. %.

Preferably, photoinitiators that are liquid at room temperature are used, which can simultaneously serve as a solvent for the dyes. Preferably, component c) can thus be used as a component of a solvent for a dye concentrate.

A further object of the invention is therefore a process in which component c) of the photo-polymerising composition according to the invention is used as a solvent or as a constituent of a solvent for the dye.

Photoinitiators that yellow as little as possible under UV light are also preferred.

### Monomer-Containing Mixture

The radically curable monomer-containing mixture contains ethylenically unsaturated monomers capable of radical addition polymerisation. The proportion is preferably at least 5% by weight, preferably at least 40% by weight and particularly preferably at least 80% by weight.

The monomer-containing mixture may also contain polymeric binders such as vinyl acetate (DE 69032682 T2), PMMA or polyols in a proportion of less than 95%, preferably less than 60% by weight and particularly preferably less than 20% by weight. Instead of being embedded in a polymeric binder, the monomers can also be embedded in a polyurethane matrix (WO 2008/125229 A1, WO 2012/062655 A2).

Plasticisers and additives such as flow agents and deaerators, which improve the film properties, can also be included. Or other inert, non-crosslinking components such as triglycerides (EP 1 779 196 B1). The ingredients of the mixture are selected such that the photopolymerisable composition forms a solid layer at the latest under actinic irradiation. Preferably, the ingredients of the monomer-containing mixture ensure that refractive index differences of at least 0.005, preferably of at least 0.01 and particularly preferably of at least 0.02 can be formed when the photopolymerisable composition is suitably exposed to light. Particularly preferably, refractive index modulations with a resolution of more than 1000 lines/mm can be generated for the recording of holograms.

Preferably, the photopolymerisable composition according to the invention can form a refractive index modulation with an amplitude or Δn of at least 0.005.

The refractive index modulation Δn is calculated using Kogelnik's Coupled Wave Theory (see; H. Kogelnik, The Bell System Technical Journal, Volume 48, November 1969, Number 9 page 2909-page 2947) based on the measured diffraction efficiency (BWG) η and the layer thickness d.

For reflection holograms of surface mirrors or Lippmann-Bragg holograms, where the refractive index modulation is parallel to the surface, the following relationship applies

$$η = tan {h}^{2} ( \frac{π \cdot Δ n \cdot d}{λ} ) , \qquad ( F ‐ 1 )$$

where λ is the wavelength of the light. For thick layers, the Δn-value of the holographic recording materials can therefore be lower than for thin layers in order to achieve the same diffraction efficiency.

The diffraction efficiency can be measured with a spectrometer (e.g. CAS 140 B from Instrument Systems) at room temperature in transmitted light. This is done with perpendicular illumination. Since the hologram only reflects the wavelength that fulfils the Bragg condition, a clear absorption peak can be seen in the spectral curve at this point.

From the peak value T_{Peak} and a nearby reference value T_{Ref} on the upper baseline, the diffraction efficiency (BWG) η is calculated as follows:

$$η = ( {T}_{Ref} - {T}_{Peak} ) / {T}_{Ref}$$

The layer thickness d can be measured with a digital micrometer outside micrometer gauge. The refractive index modulation is calculated from the two measured values as follows:

$$Δ n = \frac{λ}{π \cdot d} \cdot arctan h ( \sqrt{η} ) , \qquad ( F ‐ 2 )$$

The monomer-containing mixture forms substantially clear and transparent layers which may be solid at room temperature. Particularly preferred are monomer-containing mixtures that are liquid in a temperature range from 20° C. to 150° C. The viscosity at 20° C. should be at least 2000 mPa s, preferably 10000 mPa s and particularly preferably at least 20000 mPa s.

The viscosity can be determined with a plate-plate rotational rheometer (e.g. from Haake, type 006-2805). The material is placed between two coaxial, circular plates, one of which rotates. The plates have a distance of e.g. 1 mm and a diameter of 35 mm. The viscosity can be determined from the measurement of the torque and the speed (e.g. 10 revolutions per second) (DIN53018, ISO3210).

Preferably, the monomer-containing mixture contains multiple functional monomers with at least two ethylenically unsaturated groups. The monomer-containing mixture may consist exclusively of one or more difunctional or higher functional monomers, i.e. the composition may be free of monofunctional ethylenically unsaturated monomers. Preferably, the content of monomers with at least two ethylenically unsaturated groups in component c) of the composition according to the invention is more than 10 wt. % and particularly preferably more than 30 wt. %.

The use of difunctional or higher functional monomers leads in particular to a particularly high thermal and mechanical stability of the produced holographic elements and is especially advantageous in the production of refexion holograms.

Preferred monomers having at least two ethylenically unsaturated groups are ethoxylated bisphenol A diacrylates, in particular compounds of the following formula

where

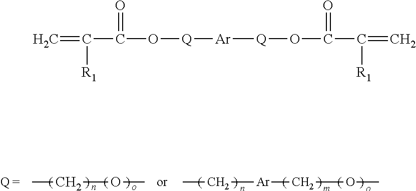

where n, m=0-12, preferably 1-12; 0=0, 1; and Ar is a mono- or polynuclear substituted or unsubstituted aromatic or heterocyclic aromatic radical and R₁ is H, methyl or ethyl.

A particularly preferred monomer is the compound of the following structural formula:

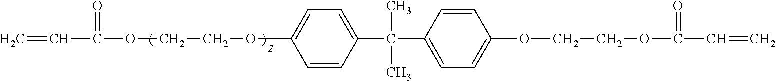

Preferably, the viscosity of the monomer or monomer mixture at room temperature is at least 900 mPas.

### Photoinitiator System

The photoinitiator system that activates the polymerisation of the monomers upon exposure to actinic radiation consists of a photoinitiator or a co-initiator or a co-photoinitiator and a dye. Preferably, it contains all three of the above components. Whereby the photoinitiator differs from the photoinitiator possibly used in the bleaching composition. Particularly preferably, the photoinitiator system or component b) contains only the co-initiator and the dye. The terms “co-initiator” and “co-photoinitiator” are used interchangeably in the context of the present invention.

The dye serves as a sensitizer that absorbs the energy of radiation from the near UV, visible or near infrared range and initiates the reaction of radical formation with the help of the co-photoinitiator.

### Dye

The dye serves as a sensitising agent for the co-photoinitiator. Suitable for this purpose are, for example, methylene blue and the sensitising agents disclosed in U.S. Pat. Nos. 3,554,753 A, 3,563,750 A, 3,563,751 A, 3,647,467 A, 3,652,275 A, 4,162,162 A, 4,268,667 A, 4,454,218 A, 4,535,052 A and 4,565,769 A, as well as the dyes and co-photoinitiators mentioned in application WO 2012062655 A2, which are expressly referred to herein. Particularly preferred sensitising agents include the following: DBC, i.e., 2,5-bis[(4-diethylamino-2-methylphenyl)methylene]cyclopentanone; DEAW, i.e., 2,5-bis[(4-diethylaminophenyl)methylene]cyclopentanone; dimethoxy-JDI, i.e., 2,3-dihydro-5,6-dimethoxy-2-[(2,3,6,7-tetrahydro-1H,5H-benzo[i,j]quinolizin-9-yl)methylene]-1H-inden-1-one; and safranin O, i.e., 3,7-diamino-2,8-dimethyl-5-phenyl-phenazinium chloride.

Preferably, the dye in the photopolymerisable composition according to the invention is a fluorescent dye, which may for example consist of a cationic dye and an anion. The cationic dye may be represented by the formula F⁺.

Therefore, by a cationic dye of the formula F⁺ one understands preferably those of the following formulae:

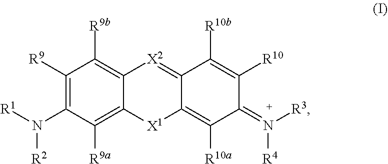

wherein
X¹ represents O, S, N—R⁶ or CR^{6a}R^{6b},
X² represents N or C—R⁵,
R⁵ represents hydrogen, cyano, C₁- to C₄-alkyl, C₄- to C₇-cycloalkyl, C₆- to C₁₀-aryl optionally substituted by C₁- to C₄-alkoxycarbonyl or NR⁷R⁸, a heterocyclic radical or C₆- to C₁₀-aryl substituted by a carboxyl group,
R⁶ represents hydrogen, C₁- to C₁₆-alkyl, C₄- to C₇-cycloalkyl, C₇- to C₁₆-aralkyl, C₆- to C₁₀-aryl or a heterocyclic radical,
R^{6a} and R^{6b} independently of one another represent methyl, ethyl or together represent a —CH₂—CH₂—CH₂— or —CH₂—CH₂—CH₂—CH₂-bridge or represent C₆- to C₁₀-aryl substituted with a carboxyl group,
R¹ to R⁴, R⁷ and R⁸ independently of one another represent hydrogen, C₁- to C₁₆-alkyl, C₄- to C₇-cycloalkyl, C₇- to C₁₆-aralkyl, C₆- to C₁₀-aryl or a heterocyclic radical or
NR¹R², NR⁷R⁴ and NR⁷R⁸ independently of one another represent a five- or six-membered saturated ring which is attached via N and which may additionally contain an N or O and/or may be substituted by nonionic radicals, or
R¹ to R⁴, R⁷ and R⁸ independently of one another form a two- or three-membered bridge with a C atom of the benzene ring adjacent to the N atom, which bridge may contain an O or N and/or may be substituted by nonionic radicals,
R⁹, R^{9a}, R^{9b}, R¹⁰, R^{10a} and R^{10b} independently of one another represent hydrogen, halogen or C₁- to C₄-alkyl,

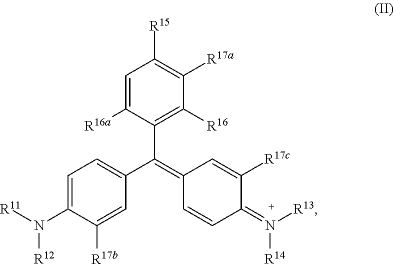

wherein
R¹⁵ represents hydrogen, halogen, C₁- to C₄-alkyl, C₁- to C₄-alkoxy or NR¹⁸R¹⁹,
R¹¹ to R¹⁴, R¹⁸ and R¹⁹ independently of one another represent hydrogen, C₁- to C₁₆-alkyl, C₄- to C₇-cycloalkyl, C₇- to C₁₆-aralkyl, C₆- to C₁₀-aryl or a heterocyclic radical or
NR¹¹R¹², NR¹³R¹⁴ and NR¹⁸R¹⁹ independently of one another represent a five- or six-membered saturated ring which is attached via N and which may additionally contain an N or O and/or may be substituted by nonionic radicals, or
R¹², R^{17b}, R¹³, R^{17c} and R¹⁸; R^{17a} independently of one another form a two- or three-membered bridge which may contain an O or N and/or may be substituted by nonionic radicals,
R¹⁶ represents hydrogen, chlorine, methyl, methoxycarbonyl or ethoxycarbonyl,
R^{16a} represents hydrogen, chlorine or methyl,
R^{17a}, R^{17b} and R^{17c} independently of one another represent hydrogen, chlorine, methyl or methoxy.

Non-ionic radicals are C₁- to C₄-alkyl, C₁- to C₄-alkoxy, halogen, cyano, nitro, C₁- to C₄-alkoxycarbonyl, C₁- to C₄-alkylthio, C₁- to C₄-alkanoylamino, benzoylamino, mono- or di-C₁- to C₄-alkylamino.

Alkyl, alkoxy, cycloalkyl, aryl and heterocyclic radicals may optionally carry further radicals such as alkyl, halogen, nitro, cyano, CO—NH₂, alkoxy, trialkylsilyl, trialkylsiloxy or phenyl, the alkyl and alkoxy radicals may be straight-chain or branched, the alkyl radicals may be partially or perhalogenated, the alkyl and alkoxy radicals may be ethoxylated or propoxylated or silylated, adjacent alkyl and/or alkoxy radicals on aryl or heterocyclic radicals may together form a three- or four-membered bridge and the heterocyclic radicals may be benzo-fused and/or quaternised.

By halogen is meant fluorine, chlorine, bromine or iodine, preferably fluorine, chlorine or bromine.

Examples of substituted alkyl groups are trifluoromethyl, chloroethyl, cyanomethyl, cyanoethyl, methoxyethyl, examples of branched alkyl groups are isopropyl, tert-butyl, 2-butyl, neopentyl. Examples of alkoxy radicals are methoxy, ethoxy, methoxyethoxy.

Preferred optionally substituted C₁- to C₄-alkyl radicals are methyl, ethyl, n-propyl, isopropyl, n-butyl, 2-butyl, iso-butyl, tert-butyl, perfluorinated methyl, perfluorinated ethyl, 2,2-trifluoroethyl, 3,3,3-trifluoroethyl, perfluorobutyl, cyanoethyl, methoxyethyl, chloroethyl.

The preferred aralkyl is, for example, benzyl, phenethyl or phenylpropyl.

Examples of C₆- to C₁₀-aryl are phenyl and naphthyl. Examples of substituted aryl radicals are tolyl, chlorophenyl, dichlorophenyl, methoxyphenyl, nitrophenyl, cyanophenyl, dimethylaminophenyl, diethylaminophenyl.

Examples of hetaryl radicals, especially five- or six-membered heterocyclic radicals, are indolyl, pyridyl, quinolyl, benzthiazolyl. Examples of substituted heterocyclic radicals are 1,2-dimethylindol-3-yl, 1-methyl-2-phenylindol-3-yl.

Anions for the cationic dyes of the formula F⁺ can be, for example, anions of halogens, sulphates, carbonates or nitrates.

Particularly suitable cationic dyes are malachite green, methylene blue, safranin O, rhodamines of the formula III

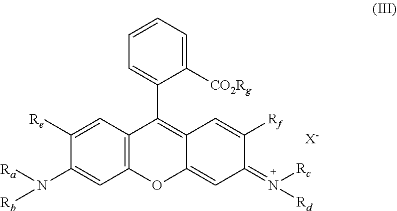

wherein Rₐ, R_{b}, R_{c}, R_{d}, Rₑ, R_{f} and R_{g} each represents H or an alkyl group, and X-represents chloride ion, trifluoromethanesulfonate, naphthalene disulfonate, para-toluenesulfonate, hexafluorophosphate, perchlorate, meta-nitrobenzenesulfonate or meta-aminobenzenesulfonate, e.g. rhodamine B, rhodamine 6 G or violamine R, further sulforhodamine B or sulforhodamine G as listed below.

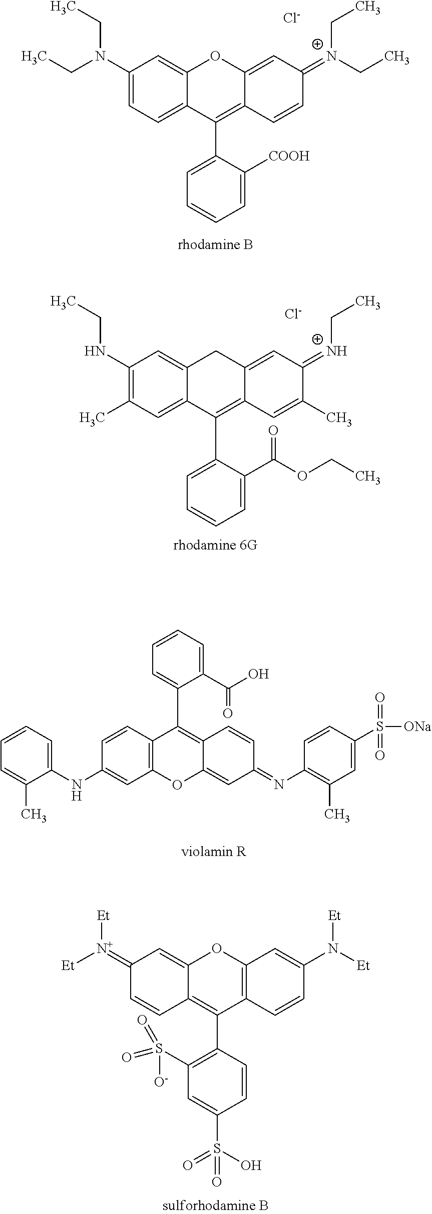

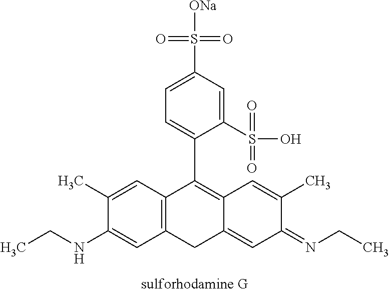

Other suitable dyes are fluorones, as described e.g. by Neckers et al. in J. Polym. Sci., Part A, Poly. Chem, 1995, 33, 1691-1703. Of particular interest is

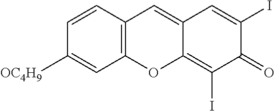

Examples of other suitable dyes are cyanines of the formula IV

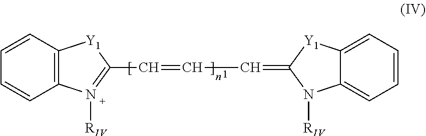

wherein R_{IV}=alkyl; n¹=0, 1, 2, 3 or 4 and Y₁═CH═CH, N—CH₃, C(CH₃)₂, O, S or Se. Preferred are cyanines wherein Y₁ in formula IV is C(CH₃)₂ or S.

Preferably, the dye in the photopolymerisable composition according to the invention is selected from the group consisting of acriflavins, diaminoacridins, rhodamine B, safranin-O, diethylsafranin and methylene blue.

### Photoinitiator

Preferably, the photoinitiator system or component b) of the photopolymerisable composition contains a photoinitiator.

Preferably, the photoinitiator in the photopolymerisable composition according to the invention is able to form radicals upon irradiation with a wavelength between 100 nm and 480 nm, preferably between 150 nm and 460 nm and more preferably between 200 nm and 380 nm.

Radical-forming polymerisation initiators are known, see e.g. Timpe, H. J. and S. Neuenfeld, “Dyes in photoinitiator system”, Contacts (1990), pages 28-35 and Jakubiak, J. and J. F. Rabek, “Photoinitiators for visible light polymisation”, Polimery (Warsaw) (1999), 44, pages 447-461.

Suitable radical-forming polymerisation initiators that can be activated by UV radiation and are generally inactive at temperatures up to 185° C. include the substituted or unsubstituted polynuclear quinones; these are compounds with two intracyclic carbon atoms in a conjugated carbocyclic ring system, e.g. 9,10-anthraquinone, 1-chloroanthraquinone, 2-chloroanthraquinone, 2-methylanthraquinone, 2-ethylanthraquinone, 2-tert-butylanthraquinone, octamethylanthraquinone, 1,4-naphthoquinone, 9,10-phenanthrenequinone, 1,2-benzanthraquinone, 2,3-benzanthraquinone, 2-methyl-1,4-naphthoquinone, 2,3-dichloronaphthoquinone, 1,4-dimethylanthraquinone, 2,3-dimethylanthraquinone, 2-phenylanthraquinone, 2,3-diphenylanthraquinone, sodium salt of anthraquinone-α-sulfonic acid, 3-chloro-2-methylanthraquinone, retenquinone, 7,8,9,10-tetrahydronaphthacenequinone and 1,2,3,4-tetrahydrobenz[a]anthracene-7,12-dione. Other photoinitiators that are also useful, although some are thermally active at temperatures as low as 85° C., are described in U.S. Pat. No. 2,760,663, and include vicinal ketaldonyl alcohols such as benzoin, pivaloin, acyloin ethers, e.g. benzoin methyl and ethyl ethers, α-hydrogensubstituted aromatic acyloins, including α-methylbenzoin, α-allylbenzoin and α-phenylbenzoin.

As photoinitiator useable are photoreducible dyes and reducing agents such as those disclosed in U.S. Pat. Nos. 2,850,445, 2,875,047, 3,097,096, 3,074,974, 3,097,097, 3,145,104 and 3,579,339, as well as dyes from the class of phenazines, oxazines and quinones; Michler's ketone, benzophenone, 2,4,5-triphenylimidazolyl dimers with hydrogen donors and mixtures thereof as described in U.S. Pat. Nos. 3,427,161, 3,479,185, 3,549,367, 4,311,783, 4,622,286 and 3,784,557. A useful discussion of dye sensitised photopolymerisation can be found in “Dye Sensitized Photopolymerization” by D. F: Eaton in Adv. in Photochemistry, vol. 13, D. H. Volman, G. S. Hammond and K. Gollnick, eds, Wiley-Interscience, New York, 1986, pp. 427-487. Similarly, the cyclohexadienone compounds of U.S. Pat. No. 4,341,860 are useful as initiators. Suitable photoinitiators include CDM-HABI, i.e., 2-(o-chlorophenyl)-4,5-bis(m-methoxyphenyl)-imidazole dimer; o-CI-HABI, i.e., 2,2-bis-(ochlorophenyl)-4,4,5,5′-tetraphenyl-1,1′-biimidazole; and TCTM-HABI, i.e., 2,5-bis(ochlorophenyl)-4-(3,4-dimethoxyphenyl)-1H-imidazole dimer, each typically used with a hydrogen donor, e.g. 2-mercaptobenzoxazole.

Particularly preferred UV photoinitiators are IRGACURE® OXE-01 (1,2-octanedione-1-[4-(phenylthio)-phenyl]-2-(O-benzoyloxime) and IRGACURE® OXE-02 (1-[9-ethyl-6-(2-methylbenzoyl)-9H-carbazol-3-yl]ethanone-O-acetyloxime from BASF AG, as well as OMNIRAD-MBF (methylbenzoyl formate), OMNIRAD-TPO (2,4,6-trimethylbenzoyl-diphenyl-phosphine oxide), OMNIRAD-TPO-L (ethyl-(2,4,6-trimethylbenzoyl)-phenylphosphinate), OMNIRAD-1173 (2-hydroxy-2-methyl-1-phenylpropanone), OMNIRAD 1000 (mixture of 2-hydroxy-2-methyl-1-phenylpropanone (80%) and 1-hydroxycyclohexyl-phenylketone (20%)), OMNIRAD 184 (1-hydroxycyclohexyl-phenylketone), OMNIRAD 819 (bis(2,4,6-trimethylbenzoyl)phenylphosphine oxide), OMNIRAD 2022 (mixture of 2-hydroxy-2-methyl-1-phenylpropanone, bis(2,4,6-trimethylbenzoyl)phenylphosphine oxide and ethyl(2,4,6-trimethylbenzoyl)phenylphosphinate) and OMNICAT 440 (4,4′-dimethyl-diphenyl-iodonium-hexafluorophosphate), which are available from IGM Resins and are preferably used in an amount of 0.1 to 10 wt. % are used.

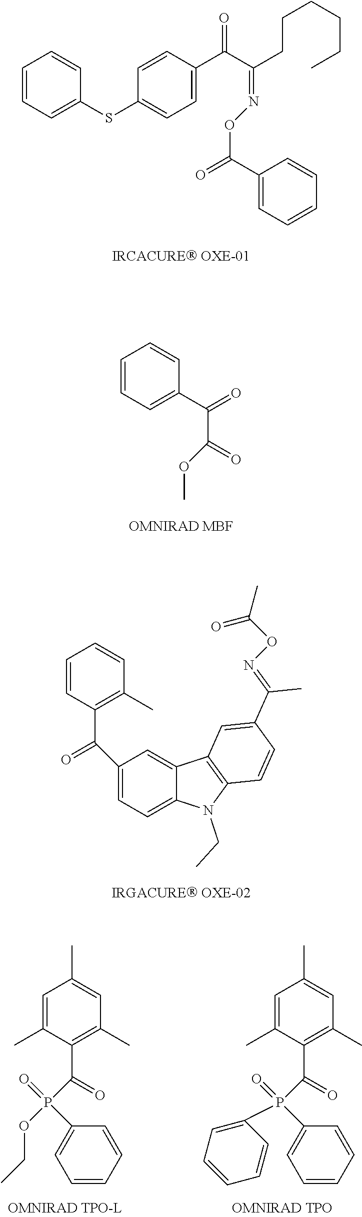

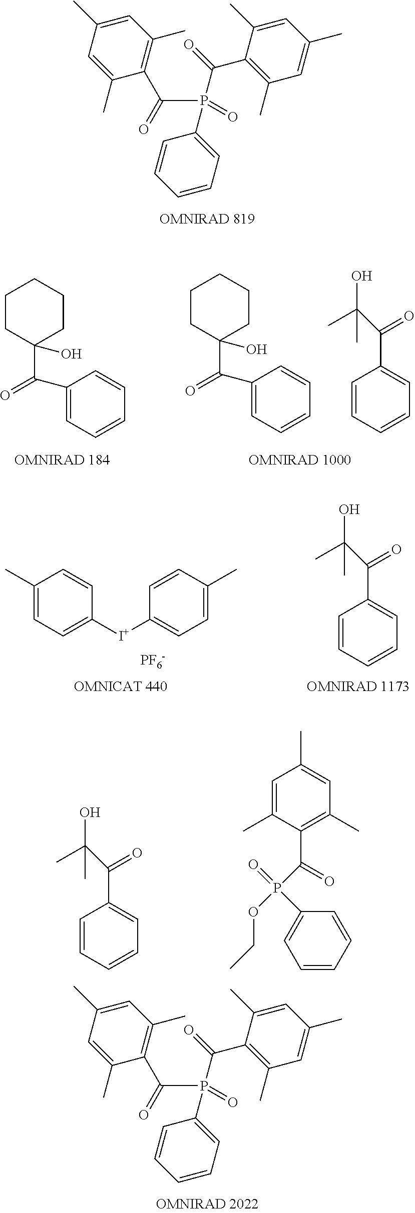

The photoinitiators mentioned above can be used alone or in combination.

Preferably, the photoinitiator is liquid and/or is selected from the group consisting of 1,2-octanedione-1-[4-(phenylthio)-phenyl]-2-(O-benzoyloxime), (1-[9-ethyl-6-(2-methylbenzoyl)-9H-carbazol-3-yl]ethanone-O-acetyloxime, methylbenzoyl formate), 2,4,6-trimethylbenzoyl diphenyl phosphine oxide, ethyl (2,4,6-trimethylbenzoyl) phenyl phosphinate), 2-hydroxy-2-methyl-1-phenyl propanone, a mixture of 2-hydroxy-2-methyl-1-phenylpropanone (80%) and 1-hydroxycyclohexyl-phenylketone (20%), 1-hydroxycyclohexyl-phenylketone, bis(2,4,6-trimethylbenzoyl)phenylphosphine oxide, a mixture of 2-hydroxy-2-methyl-1-phenylpropanone, bis(2,4,6-trimethylbenzoyl)phenylphosphine oxide and ethyl(2,4,6-trimethylbenzoyl)phenylphosphinate), and 4,4′-dimethyl-diphenyl-iodonium hexafluorophosphate.

Preferably, the photoinitiator system or component b) of the photopolymerisable composition contains a co-photoinitiator.

### Co-Photoinitiator

Preferably, the co-photoinitiator used in the composition according to the invention comprises a compound of formula (I)

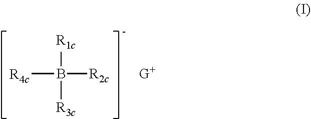

wherein
R_{1c} denotes C₁-C₂₀-alkyl, C₃-C₁₂-cycloalkyl, C₂-C₈-alkenyl, phenyl-C₁-C₆-alkyl or naphthyl-C₁-C₃-alkyl, where the radicals C₁-C₂₀-alklyl, C₃-C₁₂-cycloalkyl, C₂-C₈-alkenyl, phenyl-C₁-C₆-alkyl or naphthyl-C₁-C₆-alkyl may be interrupted with one or more groups O, S(O)ₚ or NR_{5c} or where the radicals C₁-C₂₀-alkyl, C₃-C₁₂-cycloalkyl, C₂-C₈-alkenyl, phenyl-C₁-C₆-alkyl or naphthyl-C₁-C₃-alkyl are unsubstituted or substituted by C₁-C₂-alkyl, OR₆, R_{7c}S(O)ₚ, R_{7c}S(O)₂O, NR_{8c}R_{9c}, SiR_{10c}R_{11c}R_{12c}, BR_{13c}R_{14c} or R_{15c}R_{16c}P(O)_{q}; R_{2c}, R_{3c} and R_{4c} independently of one another are phenyl or biphenyl, the phenyl or biphenyl radicals being unsubstituted or substituted by unsubstituted or by OR_{6c}, NR_{8c}R_{9c} or halogen-substituted C₁-C₁₂-alkyl, OR_{6c}, R_{7c}S(O)ₚ, R_{7c}S(O)₂O, R_{8c}R_{9c}NS(O)₂, NR_{8c}R_{9c}, NR_{3c}R_{8c}CO,

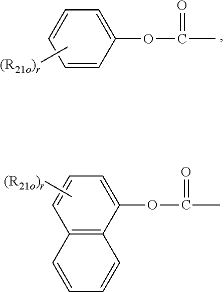

SiR_{10c}R_{11c}R_{12c}, BR_{13c}R_{14c}, Halogen, R_{15c}R_{16c}P(O)_{q},

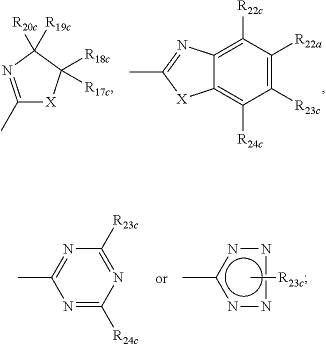

R_{5c} is hydrogen, C₁-C₁₂-alkyl, phenyl-C₁-C₆-alkyl which is unsubstituted or substituted one to five times by C₁-C₆-alkyl, C₁-C₁₂-alkoxy or halogen, or phenyl which is unsubstituted or substituted one to five times by C₁-C₆-alkyl, C₁-C₁₂-alkoxy or halogen;

R_{6c} and R_{7c} denote C₁-C₁₂-alkyl which is unsubstituted or substituted by halogen, phenyl-C₁-C₆-alkyl which is unsubstituted or substituted one to five times by C₁-C₆-alkyl, C₁-C₁₂-alkoxy or halogen, or phenyl which is unsubstituted or substituted one to five times by C₁-C₆-alkyl, C₁-C₁₂-alkoxy or halogen;

R_{8c}, R_{9c}, R_{10c}, R_{11c}, R_{12c}, R_{13c}, R_{14c}, R_{15c} and R_{16c} independently of one another C₁-C₁₂-alkyl, C₃-C₁₂-cycloalkyl, unsubstituted or substituted one to five times by C₁-C₆-alkyl, C₁-C₁₂-alkoxy or halogen substituted phenyl-C₁-C₆-alkyl or unsubstituted or one to five times with C₁-C₆-alkyl, C₁-C₁₂-alkoxy or halogen-substituted phenyl, or R_{8c} and R_{9c} together with the N atom to which they are bonded form a 6-membered aliphatic ring which may additionally contain oxygen or sulphur as a further heteroatom;

R_{17c}, R_{18c}, R_{19c} and R_{20c} independently of one another are hydrogen, C₁-C₁₂-alkyl which is unsubstituted or substituted by C₁-C₁₂-alkoxy, or phenyl or phenyl-C₁-C₆-alkyl, the radicals phenyl or phenyl-C₁-C₆-alkyl being unsubstituted or mono- to pentasubstituted by C₁-C₆-alkyl, C₁-C₁₂-alkoxy or halogen; p is a number from 0 to 2;
r represents a number from 0 to 5;
R_{21c} is hydrogen or C₁-C₁₂-alkyl;
R_{22c}, R₂₂ₐ, R_{23c} and R_{24c} independently of one another denote hydrogen, C₁-C₁₂-alkyl which is unsubstituted or substituted by C₁-C₁₂-alkoxy, OH or halogen, or phenyl which is unsubstituted or substituted by C₁-C₁₂-alkoxy, OH or halogen;
q represents 0 or 1; and
G stands for a residue which can form positive ions.

Preferably, the co-photoinitiator in the photopolymerising composition according to the invention is selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

Very preferably, a co-photoinitiator with the structural formula Ia, which was developed under the name “CGI 7460” by Ciba Specialty Chemicals Inc. and is now available from BASF AG under the name SEC LCA 1460, is presented as follows:

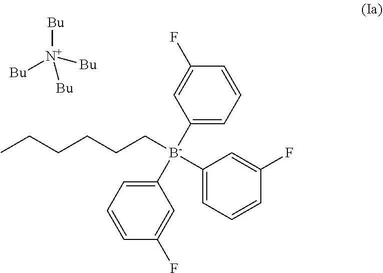

### EXAMPLES

The following dyes were used for the bleaching tests.

### Dyes

| Dye | CAS | Molecule |
|---|---|---|
| Safranin-O | 477-73-6 | 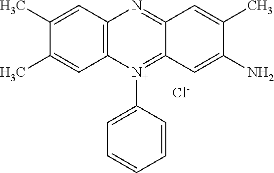 [SMILES: Cc1cc2nc3cc(C)c(N)cc3[n+](-c3ccccc3)c2cc1C ; [Cl-]] |
| Diethylsafranin | 4569-86-3 | 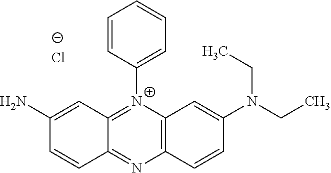 [SMILES: CCN(CC)c1ccc2nc3ccc(N)cc3[n+](-c3ccccc3)c2c1 ; [Cl-]] |
| Rhodamine-B | 81-88-9 | 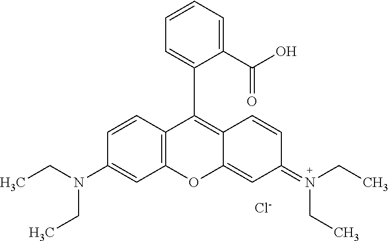 |
| Methylene blue | 61-73-4 | 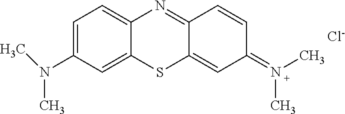 |
| Acriflavine | 8048-52-0 | 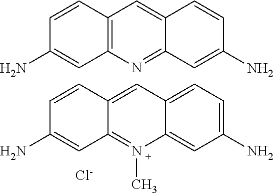 |

### UV Initiators

For the bleaching tests, these UV initiators were compared with each other.

### Liquid UV Initiators

| Brand name | CAS | Molecule |
|---|---|---|
| Omnirad MBF (IGM) | 15206-55-0 | 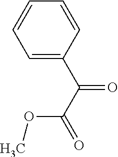 |
| Omnirad 1173 (IGM) | 7473-98-5 | 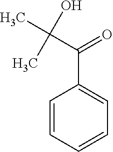 |

### Powder UV Initiators

| Brand name | CAS | Molecule |
|---|---|---|
| Omnirad 184 (IGM) | 947-19-3 | 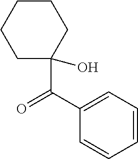 [SMILES: O=C(c1ccccc1)C1(O)CCCCC1] |
| Omnirad 819 (IGM) | 162881-26-7 | 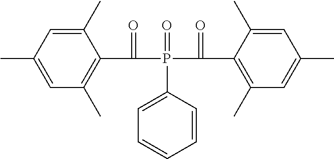 |
| Omnirad 659 (IGM) | 106797-53-9 | 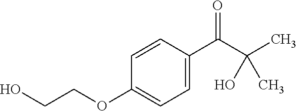 [SMILES: CC(C)(O)C(=O)c1ccc(OCCO)cc1] |
| Omnirad TPO (IGM) | 75980-60-8 | 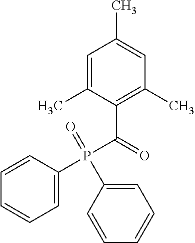 [SMILES: Cc1cc(C)c(C(=O)P(=O)(c2ccccc2)c2ccccc2)c(C)c1] |
| OXE-01 (BASF) | 253585-83-0 | 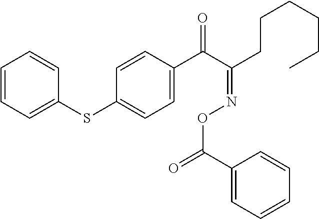 [SMILES: CCCCCC/C(=N/OC(=O)c1ccccc1)C(=O)c1ccc(Sc2ccccc2)cc1] |

### Solvent

In the bleaching tests, the following solvents were used for the dyes and the powdered UV photoinitiators. A low-molecular polycaprolactone (PCL-triol) was used as a solvent, which has no influence on bleaching.

| Designation | CAS | Molecule |
|---|---|---|
| Benzaldehyde | 100-52-7 | 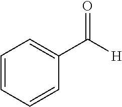 |
| 2-Propanol | 7473-98-5 | 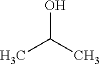 |
| Polycaprolactone triol, (PCL-triol), Mₙ ~300 | 37625-56-2 | 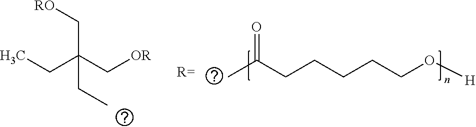 |

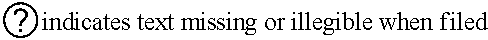

### Bleaching Tests

In order to test the suitability of the photoinitiators and solvents for improved fading of the dyes, saturated dye solutions were prepared with them. For this purpose, one to two spoon spatula tips (approx. 0.1 to 0.2 g) of the dye were placed in small 1.5 ml cuvettes. The powdered UV photoinitiators were also added with two to four spoon spatula tips (approx. 0.2 to 0.4 g) and the whole was filled up with polycaprolactone triol (PCL-triol).

For the mixtures with the liquid UV photoinitiators and solvents, it was sufficient to fill the cuvettes completely. The pure PCL-triol dye mixtures were taken as a reference, as no improved fading was observed in these solutions.

These mixtures were mixed well and kept in a 120° C. oven for one to two hours. The samples were then placed in a centrifuge to allow the undissolved components to settle to the bottom. Small amounts of the top liquid were taken with a pipette and placed as drops on a glass slide. To the right and left of these drops, another drop of the reference solution was added for comparison. The whole thing was covered with a second glass slide.

These samples could now be measured and bleached. For bleaching, the samples were placed under a UV bridge for 30 s with an arc length of 70 mm and a power of 120 W/cm. Before and after bleaching, the samples were visually inspected and the spectral absorption curves were measured with a spectrometer.

All tests showed that the dyes fade best in the Omnirad 1173 and the benzaldehyde mixture. The addition of 2-propanol to the other UV photoinitiator mixtures partially improved their effect on fading.

### Photopolymerisable Compositions

As an example of the effect according to the invention, two photopolymerisable compositions were prepared with the Safranin-O dye. First, two dye concentrates and a monomer-containing mixture were mixed.

TABLE 1
Dye concentrates FK1

| Quantity [g] | Quantity [%] | Designation | CAS |
|---|---|---|---|
| 14.7 | 73.5% | PCL-triol, Mₙ ~300 | 37625-56-2 |
| 5.0 | 25.0% | OXE-01 | 253585-83-0 |
| 0.3 | 1.5% | Safranin-O | 477-73-6 |
| 20.00 | 100.00% | | |

TABLE 2
Dye concentrate FK2

| Quantity [g] | Quantity [%] | Designation | CAS |
|---|---|---|---|
| 9.85 | 49.25% | PCL-triol, Mₙ ~300 | 37625-56-2 |
| 9.85 | 49.25% | Omnirad 1173 | 7473-98-5 |
| 0.30 | 1.5% | Safranin-O | 477-73-6 |
| 20 | 100.00% | | |

TABLE 3
Monomer-containing mixture MM1

| Quantity [g] | Quantity [%] | Designation | CAS |
|---|---|---|---|
| 287.5 | 57.16% | SR 349 | 64401-02-1 |
| 212.5 | 42.25% | Ebecryl 230 | |
| 3 | 0.60% | SEC LCA 1460 | |
| 503.00 | 100.00% | | |

For the holographic exposures, two photopolymerisable compositions were prepared from the monomer-containing mixture listed above and the two dye concentrates. The mixture with the dye concentrate FK1 was used as a comparison example.

TABLE 4
Photopolymerisable composition A

| Quantity [g] | Quantity [%] | Component | Name |
|---|---|---|---|
| 5 | 97.09% | MM1 | monomer-containing mixture |
| 0.15 | 2.91% | FK1 | Dye concentrate |
| 5.15 | 100.00% | | |

TABLE 5
Photopolymerisable composition B

| Quantity [g] | Quantity [%] | Component | Name |
|---|---|---|---|
| 5 | 97.09% | MM1 | monomer-containing mixture |
| 0.15 | 2.91% | FK2 | Dye concentrate |
| 5.15 | 100.00% | | |

### Preparation

First, the color concentrates and the monomer-containing mixture are prepared. The respective components are added one after the other into a beaker with a stirring magnet. The beaker is placed on a scale for this purpose so that the liquid substances can be added in the correct quantity. Then everything is heated to 120° C. on a heatable magnetic stirrer and stirred. The powdery substances are dosed with the help of weighing bowls and added to the mixture while stirring. The mixture is stirred at 120° C. for about 1 h before the solution is filtered and filled into a bottle.

The dye concentrates and the monomer-containing mixture are mixed (for example, by shaking with a speed mixer or stirring with a stirring rod) to produce the photopolymerisable compositions.

### Exposures

TABLE 6
Laser exposures

| | | | Thickness | Transparency |
|---|---|---|---|---|
| Material | Peak[nm] | BWG[%] | [μm] | [%] |
| A | 536 | 86% | 90 | 60 |
| B | 536 | 92% | 77 | 75 |

The photopolymerisable compositions A and B were exposed to a laser with the wavelength of 532 nm in a temperature range of 20° C. to 21° C. The photopolymerisable compositions were kept in an oven at 80° C. and exposed shortly after application. After laser exposure and rapid UV curing with a UV flash, the spectral absorption curves were measured with a spectrometer. Afterwards, the samples were post-cured for another 30 s under the UV bridge and bleached. The different bleaching of the two samples can be clearly seen visually and by measuring the spectral absorption again. The spectral absorption curve was also used to determine the diffraction efficiency (BWG, “Beugungswirkungsgrad”). The additional measurement of transparency was carried out with a hazemeter. The film thickness was measured with a digital micrometer outside micrometer gauge.

### Exposure Structure

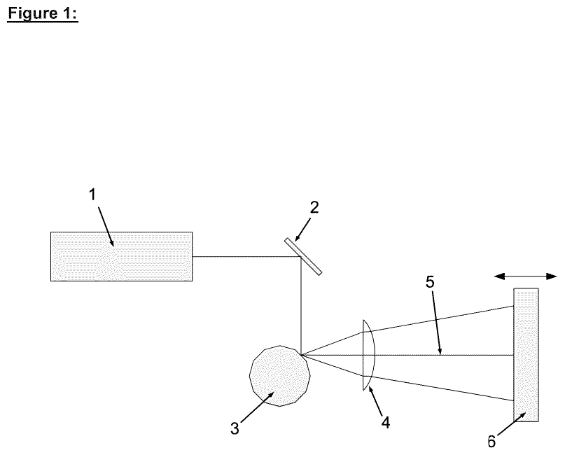

The laser beam with a measured power of 4.0 W was expanded horizontally with a polygon scanner and focused by a cylindrical lens so that it covered an exposure width of 23 cm. FIG. 1 shows the schematic exposure setup.

Reference signs in FIG. 1:
1 Laser 532 nm
2 Mirror
3 Polygon scanner
4 Cylinder lens
5 Scanning beam
6 Scanner mirror

The respective samples were scanned with this line using a movable mirror and exposed. The traversing speed was set to 9 mm/s. The laser beam fell on the sample surface at an angle of 22° to the perpendicular.

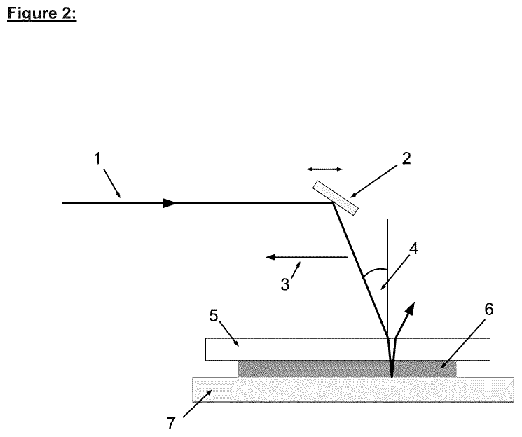

FIG. 2 shows the beam path.

Reference signs in FIG. 2:
1 Scanning beam 532 nm
2 Scanner mirror
3 Exposure direction
4 Exposure angle, 22°
5 Substrate, glass or foil
6 Photopolymer (photopolymerisable composition)
7 Master, mirror plate

To create a reflection hologram, the sample material was applied to a mirror plate which reflects the laser light back. The interference of the incident beam with the reflected beam creates a line pattern of light and dark spots parallel to the surface of the mirror. This interference pattern is recorded by the photopolymerisable composition in the form of a refractive index modulation and a so-called Lippmann-Bragg hologram is created.

With laser exposure, the photopolymer layer is between the mirror sheet and a transparent substrate, e.g. a PET film or glass. Object glass substrates were used for the examples. The glass is used to cover a drop applied to the mirror sheet. The layer thickness results from the drop quantity and the drop expansion. The size of the circular expansion can be controlled by the contact pressure, the temperature and the flow time. Spacers can also be used to achieve a certain layer thickness. After laser exposure, the photopolymerisable composition is cured with UV light. For the first curing step, a UV flash with a power of 3000 WS was used. This is sufficient to remove the hologram with the carrier from the sheet afterwards. To ensure adhesion to the glass, it should be pre-treated with a primer.

A UV bridge with an arc length of 70 mm and a power of 120 W/cm was used for the final curing and bleaching of the sample. The illuminant was a mercury vapour bulb. The exposure or bleaching time was 30 seconds.

### Measurement Setup

The samples were measured with a spectrometer (CAS 140 B from Instrument Systems) in transmitted light. This was done with perpendicular illumination. Since the hologram only reflects the wavelength that fulfils the Bragg condition, a clear absorption peak can be seen in the spectral curve at this point.

From the peak value T_{Peak} and a nearby reference value T_{Ref} on the upper baseline, the diffraction efficiency (BWG) n is calculated as follows:

$$η = ( {T}_{Ref} - {T}_{Peak} ) / {T}_{Ref}$$

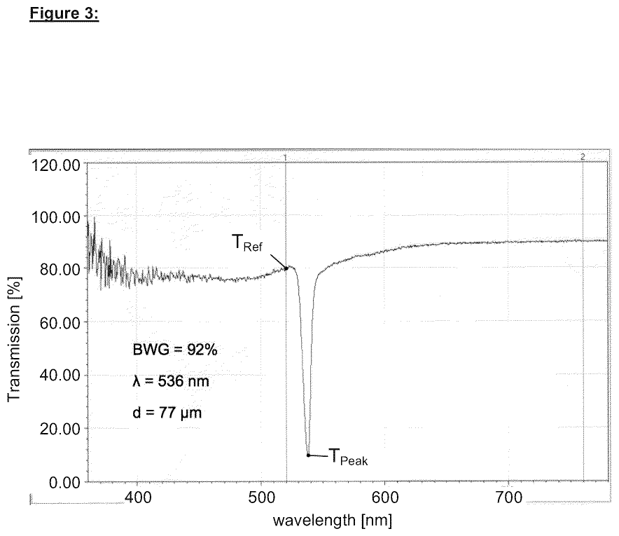

FIG. 3 shows the measurement curve with the corresponding measurement points of sample B.

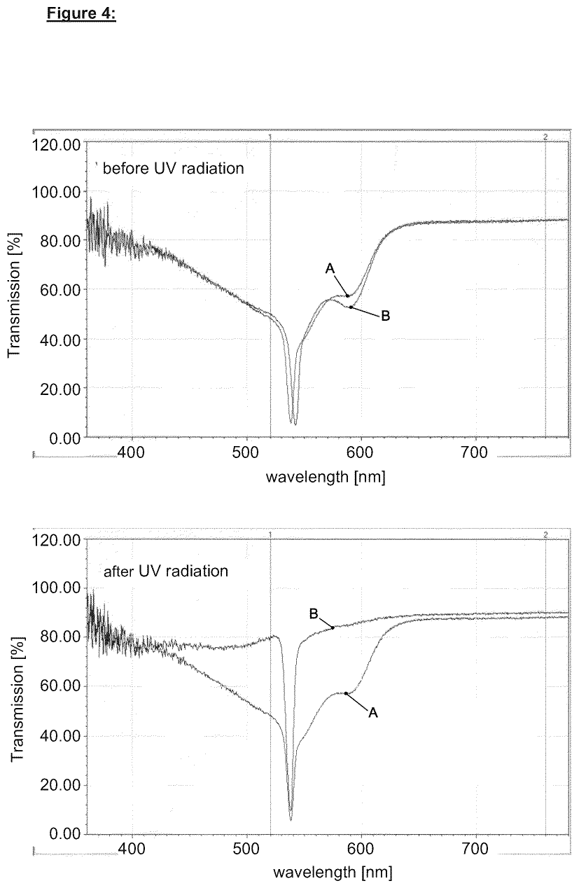

The table values of the exposures (Tab. 6) show that both samples achieve a high diffraction efficiency of over 80%, but exposure sample B is much more transparent. FIG. 4 shows the spectral absorption curves of the two photopolymerized compositions A and B before and after the 30 s bleaching under the UV bridge.

The transparency values were measured with a hazemeter (haze-gard i from BYK) using a 4 mm aperture diaphragm according to the ASTM D 1003 standard procedure.

1-15. (canceled)

16. A photopolymerizable composition curable by UV/VIS irradiation comprising:
(a) from 80% to 99.8% by weight of a radically curable monomer-containing mixture,
b) from 0.1% to 10% by weight of a photoinitiator system, and
c) from 0.1% to 10% by weight of a bleaching agent,
wherein the total amount of a), b) and c) is 100% by weight,
wherein the bleaching agent is effective under actinic irradiation,
wherein the photoinitiator system contains a dye and a co-initiator,
wherein component c) contains photoinitiators, and
wherein the photoinitiators used in component c) generate benzoyl and alcohol radicals under the action of actinic radiation.

17. The photopolymerizable composition according to claim 16,
wherein the co-initiator is selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

18. The photopolymerizable composition according to claim 16, wherein the dye is selected from the group consisting of acriflavins, diaminoacridins, rhodamine B, safranin-O, diethylsafranin and methylene blue.

19. The photopolymerizable composition according to claim 16, wherein bleaching substances are formed by the action of actinic radiation from component c).

20. The polymerizable composition of claim 16, wherein the polymerizable composition is capable of forming a refractive index modulation having an amplitude or Δn of at least 0.005.

21. An element comprising a component obtainable by the action of UV/VIS radiation on the photopolymerizable composition according to claim 16.

22. The element according to claim 21, comprising a hologram obtainable by exposing the photopolymerizable composition to spatially or interferometrically modulated radiation.

23. A film, lens, grating, prism, mirror, beam splitter, diffuser, surface relief, optical switch or sensor comprising the element according to claim 21.

24. A head-up display, a laminated glass pane, data glasses, light guidance system, spectrometer, detection system, security element or label comprising the element according to claim 21.

25. A method of manufacturing the element according to claim 21, wherein UV light is used to post-bleach the element.

26. A process in which component c) of the photopolymerizing composition according to claim 16 is used as a solvent or as a constituent of a solvent for the dye.

27. A method of forming a light stable hologram in a photopolymerizable layer on a substrate surface or a copy master, comprising exposing a layer of the photopolymerizable composition according to claim 16 to modulated radiation carrying holographic information.

28. The element according to claim 21, wherein the UV/VIS radiation is actinic UV/VIS radiation.
